(19) United States
(12) Patent Application Publication
(10) Pub. No.: US 2007/0092810 A1
(43) Pub. Date: Apr. 26, 2007

(54) Mask-less method of forming aligned semiconductor wafer features

(76) Inventor: Shoaib Zaidi, Poughkeepsie, NY (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/257,276

(22) Filed: Oct. 24, 2005

(51) Int. Cl. G03F 7/20

(52) U.S. Cl. 430/30; 430/311

(57) ABSTRACT

A method of forming features in a semiconductor is disclosed. The method includes providing a wafer substrate including a surface having a reflective region, and coating the surface with a photosensitive layer. The method additionally includes exposing the photosensitive layer. The method further includes controlling exposure intensity such that the photosensitive layer has an exposed area only in an area adjacent the reflective region.

### BACKGROUND

Semiconductor fabrication plays an important role in the growth of the electronics industry. Increased memory capacity and increased computational speed both relate to the fabrication of ever-smaller features on semiconductor wafer substrates. Traditionally, lithography (also known as photolithography) is employed to pattern the above-mentioned small features onto semiconductor wafer substrates.

Lithography is a mature and widely understood technology. Known semiconductor-manufacturing processes rely upon lithography technology to create the fine features of each integrated circuit. Lithography technology includes applying a photosensitive layer onto each substrate layer and subjecting the photosensitive layer to a mask process. A mask is formed by coating an ultra-pure glass plate with chromium. Computer generated layouts of a desired integrated circuit pattern are formed by selectively removing the chromium with a laser or electron beam. The mask is then precisely aligned over the photosensitive layer, and a high intensity light is directed to the mask and toward the photosensitive layer. Each substrate layer is defined by the specific mask (formed as described above), and for a given integrated circuit, 16 to 24 masks are employed. Lithography accounts for approximately one-third of the wafer fabrication budget.

Lithography is a costly and widely used technology. Lithography processing employs costly masks, tedious and complicated alignment routines for the mask relative to features on previously produced layers, and a variety of anti-reflective coatings in an attempt to ensure accurate control over which portion of the substrate is exposed to light.

For these and other reasons, there is a need for more economical and efficient methods of fabricating fine features onto semiconductor wafers.

### SUMMARY

One aspect of the present invention provides a method of forming features in a semiconductor. The method includes providing a wafer substrate including a surface having a reflective region, and coating the surface with a photosensitive layer. The method additionally includes exposing the photosensitive layer. The method further includes controlling exposure intensity such that the photosensitive layer has an exposed area only in an area adjacent the reflective region.

### BRIEF DESCRIPTION OF THE DRAWINGS

The accompanying drawings are included to provide a further understanding of the present invention and are incorporated in and comprise a part of this specification. The drawings illustrate embodiments of the present invention and together with the detailed description describe principles of the present invention. Other embodiments of the present invention, and many of the intended advantages of the present invention, will be readily appreciated as they become better understood by reference to the following detailed description. The elements of the drawings are not necessarily to scale relative to each other. Like reference numerals designate corresponding similar parts.

FIG. 1 illustrates a cross-sectional view of a portion of a semiconductor wafer comprising a substrate including plugs and features aligned with the plugs according to one embodiment of the present invention.

FIG. 2 illustrates a top planar view of a semiconductor wafer substrate comprising plugs disposed in a dielectric field.

FIG. 3 illustrates a cross-sectional view along line 3-3 of the semiconductor wafer substrate illustrated in FIG. 2.

FIG. 4 illustrates a cross-sectional view of a photosensitive layer deposited atop the semiconductor wafer substrate illustrated in FIG. 3.

FIG. 5 illustrates a cross-sectional view of an alternate embodiment of a transparent layer disposed on the semiconductor wafer substrate illustrated in FIG. 3 and including a photosensitive layer disposed on the transparent layer.

FIG. 6 illustrates a cross-sectional view of the substrate and photosensitive layer illustrated in FIG. 4 exposed to a flood of incident light according to one embodiment of the present invention.

FIG. 7 illustrates a cross-sectional view of the semiconductor wafer substrate and photosensitive layer after exposure of portions of the photosensitive layer to incident and reflected light according to one embodiment of the present invention.

FIG. 8 illustrates a cross-sectional view of the semiconductor wafer substrate illustrating a removal of exposed soluble positive photoresist immediately above the plugs in a wash process according to one embodiment of the present invention.

FIG. 9A illustrates a cross-sectional view of features formed on the plugs of a substrate formed by a mask-less self aligned process according to one embodiment of the present invention.

FIG. 9B illustrates a cross-sectional view of another embodiment of features formed on the plugs of a substrate formed by a mask-less self aligned process according to one embodiment of the present invention.

FIG. 10 illustrates a cross-sectional view of a semiconductor wafer substrate including plugs disposed in a dielectric field and including exposed negative photoresist material aligned on the plugs according to one embodiment of the present invention.

FIG. 11 illustrates a cross-sectional view of a semiconductor wafer substrate including a negative photoresist layer coated onto a surface of the substrate.

FIG. 12 illustrates a cross-sectional view of an alternate embodiment of a semiconductor wafer substrate including a transparent layer deposited on a surface of the substrate and including a negative photoresist layer on the transparent layer according to one embodiment of the present invention.

FIG. 13 illustrates a cross-sectional view of a flood of incident light directed to a negative photoresist layer on a semiconductor wafer substrate according to one embodiment of the present invention.

FIG. 14 illustrates a cross-sectional view of exposed insoluble negative photoresist aligned above plugs and soluble photoresist space between the plugs according to one embodiment of the present invention.

FIG. 15 illustrates a cross-sectional view of the wafer layers illustrated in FIG. 14 after a wash process to remove the soluble negative photoresist.

FIG. 16 illustrates a cross-sectional view of the wafer layers illustrated in FIG. 15 after deposition of a feature between the insoluble negative photoresist portions according to one embodiment of the present invention.

FIG. 17 illustrates a plot of relative light intensity incident to a photosensitive layer and regions of increased intensity due to reflected incident light according to one embodiment of the present invention.

FIG. 18 illustrates a lower portion of photosensitive layer receiving a greater intensity of threshold radiation in forming a feature having a sub-lithographic dimension atop a sub-lithographic plug according to one embodiment of the present invention.

### DETAILED DESCRIPTION

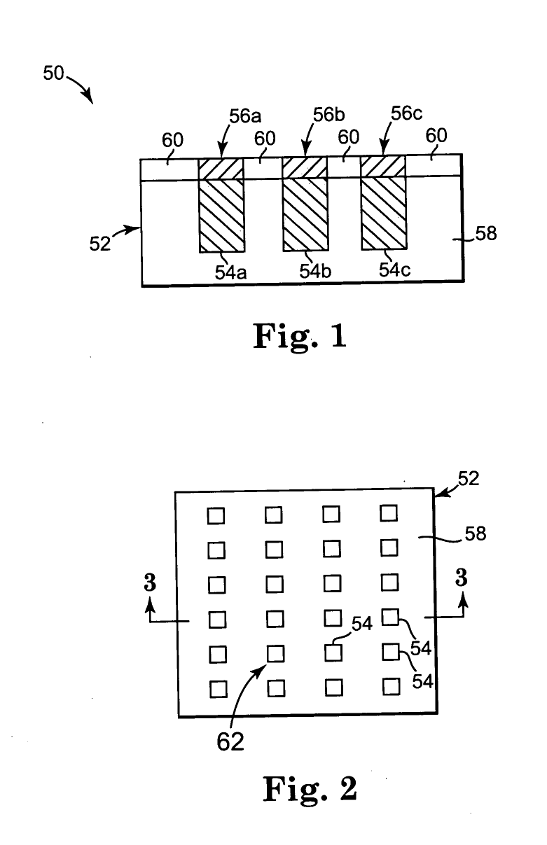

FIG. 1 illustrates a cross-sectional view of a portion of a semiconductor wafer 50 according to one embodiment of the present invention. The semiconductor wafer 50 includes a substrate 52 including a plurality of plugs 54a, 54b, 54c having respective features 56a, 56b, 56c aligned with plugs 54a, 54b, 54c. Wafer 50 is illustrated in an intermediate stage of fabrication, and as such, can include other layers that are not illustrated in the particular stage depicted.

In one embodiment, substrate 52 includes a dielectric field 58 and a plurality of plugs 54 disposed within dielectric field 58. In various embodiments described in further detail below, the semiconductor wafer 50 includes a photosensitive layer 60 disposed on top of substrate 52. Semiconductor wafer 50 is processed to include plugs 54 and self-aligned features 56 disposed on top of plugs 54. A mask-less wafer process according to embodiments of the present invention forms features that are self-aligned relative to plugs 54.

In one embodiment, plugs 54 are “resistive” plugs that are electrically conductive and configured to resistively heat, and consequently change a physical state of, a programmable material in contact with plugs 54. Plugs 54 in one embodiment are metal plugs formed, for example, of copper, tungsten, titanium, gold, or alloys of metal in general, although other electrically conductive materials are also suitable for use with the present invention.

In one embodiment, features 56 include programmable semiconductor material. In one embodiment, the programmable semiconductor material is a phase change material that can be electrically (i.e., thermally) switched between states to create a multi-level memory. In one embodiment, the phase change material is a chalcogenide alloy of elements of group VI of the periodic table, such as Te, Se, or Sb. For example, in one embodiment the phase change material is a chalcogenide alloy represented by Ge₂Sb₂Te₅. In another embodiment, the phase change material is an alloy of AgInSbTe. In other embodiments, the feature 56 includes titanium nitride having a resistivity of between 30-70 ohm-cm and a melting point of approximately 2950 degrees Celsius. In another embodiment, the feature 56 includes titanium silicon nitride.

One characteristic of phase change materials in general, and chalcogenides in particular, is that the electrical resistivity varies between an amorphous state and a crystalline state(s), and this characteristic can be beneficially employed in two level or multiple level memory systems where the resistivity is either a function of the bulk material or a function of the partial material. As a point of reference, a chalcogenide can be selectively switched between the amorphous state (exhibiting a disordered structure, for example, like a frozen liquid) and the crystalline state(s) (exhibiting a regular atomic structure). In this manner, manipulating the states of the chalcogenide permits a selective control over the electrical properties of the chalcogenide, which is useful in the storage and retrieval of data from the memory cell containing the chalcogenide.

The atomic structure of the chalcogenide can be selectively changed by the application of energy. With regard to chalcogenides in general, at below temperatures of approximately 150 degrees Celsius both the amorphous and crystalline states are stable. A nucleation of crystals within the chalcogenide can be initiated when temperatures are increased to the crystallization temperature for the particular chalcogenide (approximately 200 degrees Celsius). In particular, the atomic structure of a chalcogenide becomes highly ordered when maintained at the crystallization temperature, such that a subsequent slow cooling of the material results in a stable orientation of the atomic structure in the highly ordered (crystalline) state. To achieve the amorphous state in the chalcogenide material, the local temperature is generally raised above the melting temperature (approximately 600° C.) to achieve a highly random atomic structure, and then rapidly cooled to “lock” the atomic structure in the amorphous state.

In one embodiment, features 56 are engineered features comprising sub-lithographic volumes of, for example, phase change material. Sub-lithographic volumes of phase change material enable the use of a relatively smaller reset current, voltage or power, flowing through plugs 54 to initiate a switching between memory states in the phase change material. Wafer 50 illustrates one embodiment of a sub-lithographic critical dimension (CD) feature that responds to a minimum of current, voltage, and power in activating memory cells (not shown) of wafer 50.

FIG. 2 illustrates a top planar view of a surface 62 of substrate 52 according to one embodiment of the present invention. Plugs 54 are disposed in dielectric field 58. As illustrated, plugs 54 are rectangular in cross-section, although other cross-sectional shapes of plugs 54 are also suitable (i.e., cylindrical). In one embodiment, plugs 54 are electrically conductive and form a conductive electrode. In an alternate embodiment, plugs 54 are semiconductor plugs having an increased resistivity. Plugs 54 are in general more light reflective than dielectric field 58. Thus, plugs 54 reflect light relative to dielectric field 58, and dielectric field 58 absorbs light relative to plugs 54, in general.

Dielectric field 58 is in general an insulating field and can be an oxide field, a nitride field, or any other dielectric having suitable thermal etch and electrical characteristics.

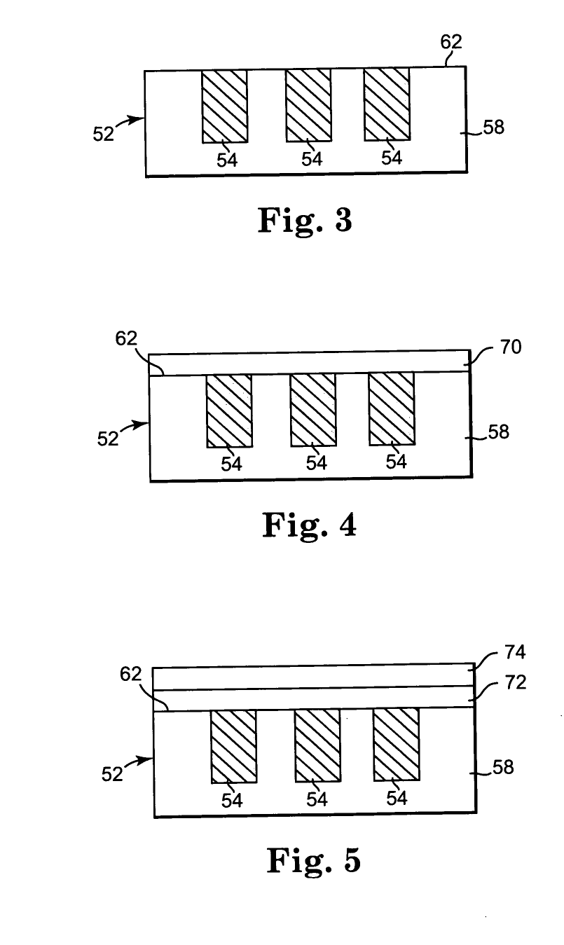

FIGS. 3-9B illustrate a mask-less method of fabricating semiconductor features according to one embodiment of the present invention.

FIG. 3 illustrates a cross-sectional view of substrate 52 according to one embodiment of the present invention. Substrate 52 defines surface 62 that includes exposed plugs 54 surrounded by dielectric field 58. In this regard, surface 62 includes at least one light reflective region in the form of plugs 54 exposed on surface 62 and surrounded by dielectric field 58. Plugs 54 reflect light, and dielectric field 58 absorbs light, thus surface 62 includes light reflective regions where the plugs 54 are exposed and a substantially non-reflective region where dielectric field 58 is exposed.

FIG. 4 illustrates a cross-sectional view of substrate 52 including a photosensitive layer 70 according to one embodiment of the present invention. In one embodiment, photosensitive layer 70 includes a positive photoresist layer disposed on surface 62. Positive photoresist photosensitive layer 70 is substantially insoluble in a developing solution, and as such, does not wash away during a subsequent wash/removal process. However, photosensitive layer 70 reacts chemically to radiation in various forms, and can be “exposed” to change its material property of solubility from generally insoluble to soluble. For example, in one embodiment a portion of photosensitive layer 70 is exposed to a high intensity light source (either ultraviolet light or a visible light) and made soluble in developing solution. In this manner, a subsequent wash process will remove the exposed and soluble portion of photosensitive layer 70.

FIG. 5 illustrates a cross-sectional view of an alternate embodiment of substrate 52 including a transparent layer 72 according to one embodiment of the present invention. Transparent layer 72 is disposed on and is in contact with surface 62. Transparent layer 72 may be formed of one or more transparent films, however, only one transparent film is illustrated in FIG. 5. A general photoresist layer 74 is disposed on transparent layer 72. General photoresist layer 74 can be either a positive photoresist or a negative photoresist. Transparent layer 72 is transparent to light radiation such that light incident to the general photoresist layer 74 penetrates to interact with surface 62 (i.e., reflect off of plugs 54), as more fully described below.

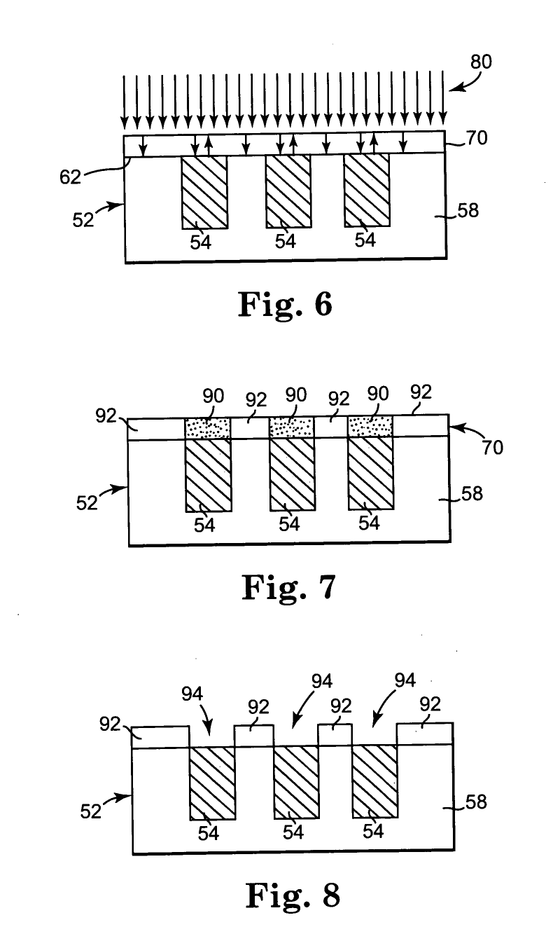

FIG. 6 illustrates printing photoresist layer 70 with incident light 80 according to one embodiment of the present invention. Incident light 80 is printed in a “flood” or blanket of incident radiation. The flood printing of incident light 80 does not employ costly masks and bottom anti-reflective coatings commonly used in the photolithographic processing of semiconductor substrates.

Incident light 80, in general, is a radiation source having a wavelength selected to alter the chemical resistance (e.g., solubility) of photosensitive layer 70. Incident light 80 penetrates photosensitive layer 70. In one embodiment, incident light 80 is below a threshold exposure value such that photosensitive layer 70 is not exposed in the regions where photosensitive layer 70 is in contact with dielectric field 58. This phenomenon is represented by a single arrow within photosensitive layer 70 indicating that dielectric field 58 absorbs incident light 80.

In contrast, portions of incident light 80 is reflected from plugs 54 such that a threshold energy is exceeded in a portion of the photosensitive layer 70 immediately above plugs 54. This phenomenon is represented by a dual arrow within photosensitive layer 70 (immediately above plugs 54) indicating that plugs 54 reflect the incident light 80 back into photosensitive layer 70, thus effectively increasing a local dose of radiation. In particular, incident light 80 streams to plugs 54 and is reflected back into photosensitive layer 70. Thus, in one embodiment incident light 80 combines with reflected light from plugs 54 to additionally dose photosensitive layer 70 with radiation in the region immediately above plug 54. In this manner, radiation exposure in a region immediately above plugs 54 exceeds a threshold energy level. A portion of photosensitive layer 70 immediately above light reflective plugs 54 is exposed to a threshold energy level sufficient to alter its chemical property of solubility.

FIG. 7 illustrates positive photoresist photosensitive layer 70 after exposure to incident light 80 according to one embodiment of the present invention. Positive photoresist photosensitive layer 70 includes regions of exposed photoresist 90 and regions of unexposed photoresist 92. In one embodiment exposed regions of photoresist 90 are now soluble and unexposed regions 92 of positive photoresist photosensitive layer 70 maintain their physical characteristic of being substantially insoluble in developer solution. Exposed regions 90 have undergone a physical property change due to the expose of incident and reflected light (the dual arrows in FIG. 6) and have been processed to become soluble in developer solution.

FIG. 8 illustrates a cross-sectional view of exposed portions 90 of photoresist layer 70 (FIG. 7) after a removal process according to one embodiment of the present invention. Thus, FIG. 8 illustrates a removal of the soluble portions 90 of exposed photosensitive layer 70. In one embodiment the exposed portions 90 are washed (i.e., removed) by developer solution in an etch process. Thereafter, recesses 94 are formed in the unexposed portions 92 of photosensitive layer 70. Recesses 94 are precisely aligned above plugs 54 and have been formed in a “mask-less” process.

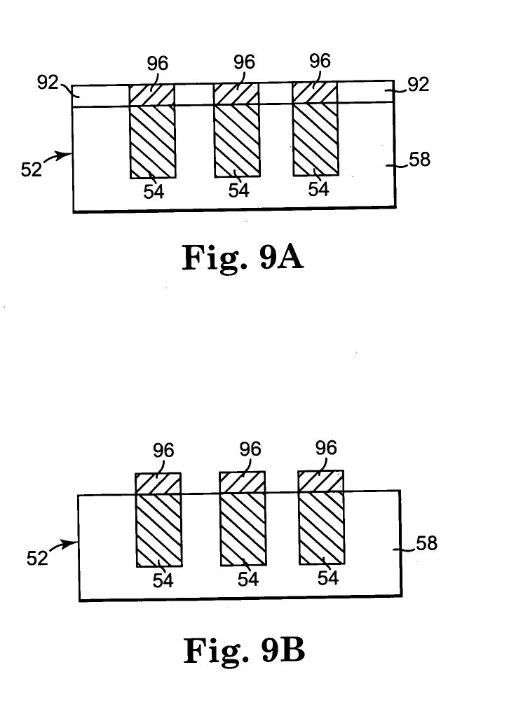

FIG. 9A illustrates a cross-sectional view of features 96 contacting plugs 54 according to one embodiment of the present invention. In this regard, recesses 94 (FIG. 8) have been filled with a selected deposition of material to form features 96 in contact with plugs 54. Features 96 are “self-aligned” with plugs 54, meaning that an overlay has not been employed in accurately aligning features 96 with plug 54. In addition, features 96 are aligned relative to plugs 54.

In one embodiment, features 96 are programmable elements including, for example, a phase change material, as described above. In another embodiment, features 96 are metallic features. In yet another embodiment, features 96 include an inorganic material disposed in contact with plugs 54.

FIG. 9B illustrates a cross-sectional view of features 96 after an optional etch and removal process according to one embodiment of the present invention. In this regard, an optional etch/removal process has been employed to remove unexposed portions 92 (FIG. 9A) of photosensitive layer 70 (FIG. 7). In this manner, features 96 are self-aligned to plugs 54 and have been formed in a mask-less process according to one embodiment of the present invention as illustrated by FIGS. 2-8 above.

In one embodiment, features 96 include at least one sub-lithographic dimension of less than approximately 50 nanometers, more preferably features 96 define a sub-lithographic dimension of less than approximately 30 nanometers, and most preferably features 96 are mask-lessly self-aligned and include a sub-lithographic dimension of approximately 20 nanometers. In other embodiments, features 96 have super-lithographic dimensions of 100 nm or larger (i.e., features 96 are dimensionally larger than sub-lithographic). Features 96 can be deposited by chemical vapor deposition (CVD), atomic layer deposition (ALD), metal organic chemical vapor deposition (MOCVD), plasma vapor deposition (PVD), jet vapor deposition (JVD), or other suitable deposition techniques to provide a suitable sub-lithographic dimension as described above.

In one embodiment, features 96 include a phase-change material and plugs 54 include a resistive element, as also described above. Phase-change features 96 define a minimum feature size (in one embodiment a sub-lithographic feature size) such that a reset current applied through resistive plugs 54 can be minimized. The minute volume of phase-change material provided by features 96 enable lower current/power/voltage to be employed to effect a change of state in phase-change material of features 96.

It is to be understood from the description above that the portion of semiconductor wafer 50 illustrated is representative of one stage (or several stages) in the fabrication of wafer 50. That is to say that although a mask-less process has been described that forms self-aligned features 96 within one “layer” of wafer 50, it is to be understood that multiple such fabrication steps could be employed to structure multiple layers of wafer 50 without any overlay or mask processing steps.

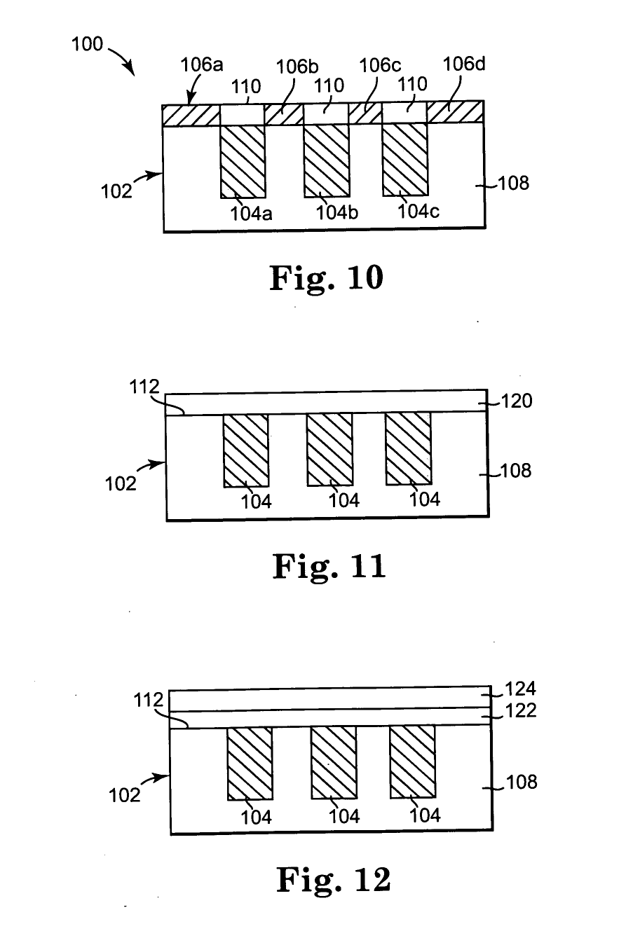

FIG. 10 illustrates a cross-sectional view of a semiconductor wafer portion 100 according to another embodiment of the present invention. Semiconductor wafer portion 100 includes a substrate 102 including plugs 104a, 104b, 104c and features 106a, 106b, 106c, and 106d. Substrate 102 comprises a dielectric field 108 containing plugs 104a-104c and is highly similar to substrate 52 illustrated in FIGS. 2 and 3. Features 106a-106d are formed to self-align relative to plugs 104. A remaining negative photoresist portion 110 sits atop plugs 104 such that features 106 are aligned offset from and relative to plugs 104, as is more fully described below.

FIG. 11 illustrates a cross-sectional view of substrate 102 including a negative photoresist layer 120 according to one embodiment of the present invention. Substrate 102 defines a surface 112 that includes at least one light reflective region (i.e., plugs 104) adjacent to a substantially non-reflective region (dielectric field 108). In one embodiment, negative photoresist layer 120 includes a photosensitive material that is completely soluble in developer solution, unless cured or exposed to be made insoluble, as more fully described below.

FIG. 12 illustrates a cross-sectional view of substrate 102 including an optional transparent layer 122 in contact with surface 112 according to one embodiment of the present invention. Transparent layer 122 is optically transparent to incident light radiation. As illustrated, a photosensitive layer 124 contacts optional transparent layer 122. In one embodiment, photosensitive layer 124 is a negative photoresist layer. Light incident to negative photoresist photosensitive layer 124 can be transmitted and reflected from plugs 104 to control a level of radiation exposure to photosensitive layer 124, consistent with various embodiments of the present invention.

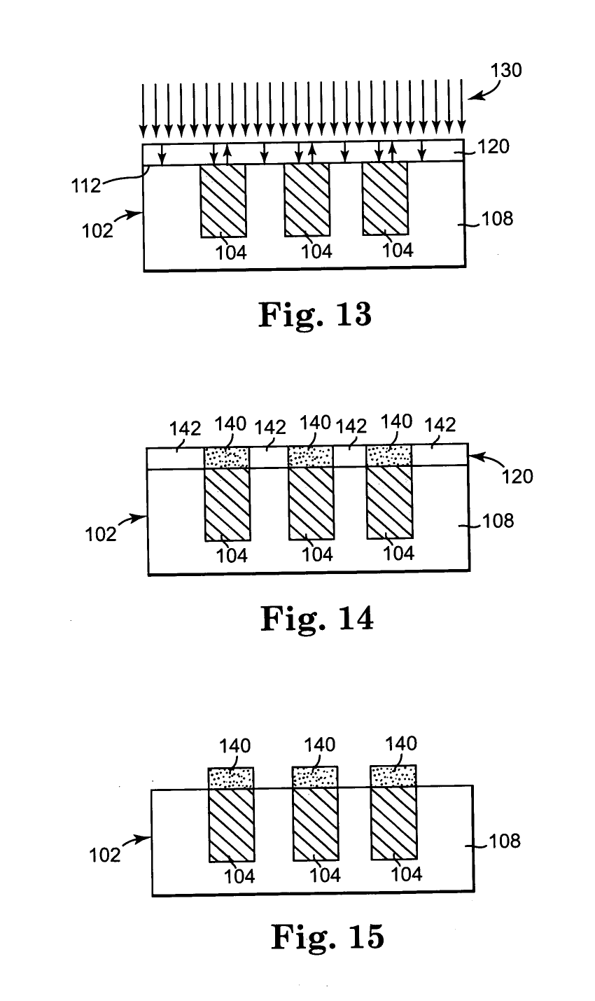

FIG. 13 illustrates a cross-sectional view of substrate 102 including negative photoresist layer 120 subjected to incident light 130 according to one embodiment of the present invention. In one embodiment, incident light 130 is a flood exposure or block exposure of radiation directed to negative photoresist layer 120. In one embodiment, the block exposure of incident light 130 is applied in a “printing” process where the negative photoresist layer 120 is subjected to incident light of a selected dose. In accordance with aspects of the present invention, incident light 130 and light reflected from the plugs 104 (represented by dual arrows in layer 120) combine to expose and make insoluble the negative photoresist layer 120 immediately above plugs 104. That is to say, portions of negative photoresist layer 120 receive only incident light controlled to be below a threshold energy value (represented by a single arrow in layer 120) such that portions of negative photoresist layer 120 are unexposed, and other portions of negative photoresist layer 120 (i.e., immediately above plugs 104) are exposed by incident and reflected radiation and chemically altered to be insoluble.

FIG. 14 illustrates a cross-sectional view of exposed portions 140 and unexposed portions 142 of negative photoresist layer 120 on substrate 102 according to one embodiment of the present invention. Exposed portions 140 of negative photoresist layer 120 immediately above plugs 104 have been exposed to a level of radiation above a threshold energy value such that the negative photoresist layer 120 in the exposed portions 140 is chemically altered and made insoluble. In contrast, unexposed portions 142 of negative photoresist layer 120 receive only incident radiation below a threshold energy level such that the unexposed portions 142 remain completely soluble in developer solution.

FIG. 15 is a cross-sectional view of substrate 102 after selective removal of unexposed portions 142 of negative photoresist layer 120 (FIG. 14) according to one embodiment of the present invention. Exposed portions 140 of negative photoresist layer 120 (FIG. 14) remain deposited on top of plugs 104.

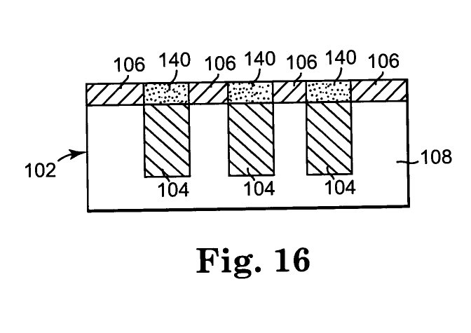

FIG. 16 illustrates a cross-sectional view of features 106 disposed on substrate 102 according to one embodiment of the present invention. Features 106 are self-aligned and offset relative to plugs 104. Exposed portions 140 of negative photoresist layer 120 (FIG. 14) remain spaced between features 106 (and atop plugs 104). In a subsequent process, exposed portions 140 can be removed in an etching process (similar to the removal described in FIG. 8 above) to define features 106 aligned and offset from plugs 104 according to embodiments of the present invention.

Subsequent fabrication of wafer 100 (FIG. 10) can include multiple other mask-less processes where other features are formed on other layers of wafer 100 without employing overlay frames, bottom anti-reflective coatings, or masks.

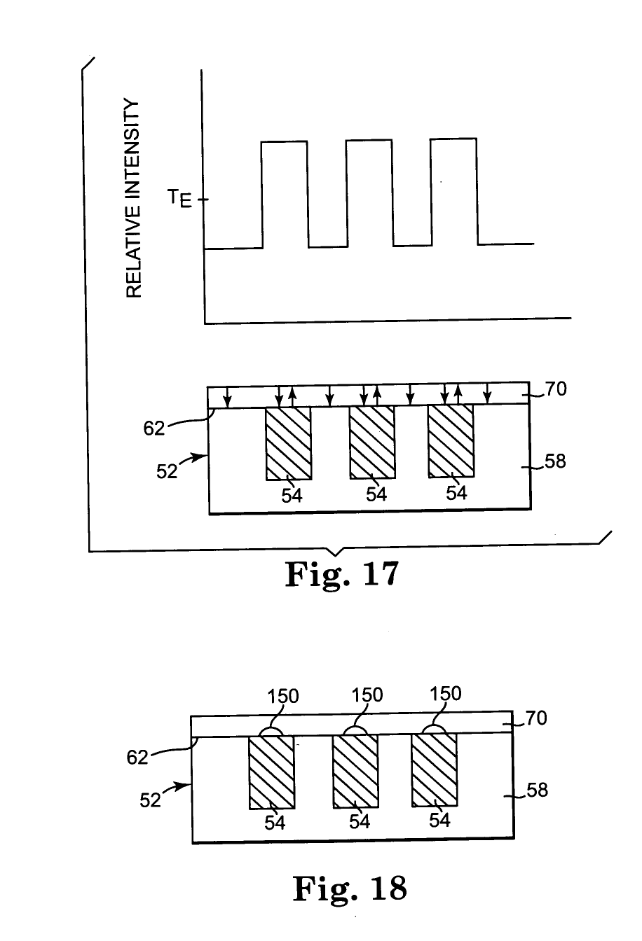

FIG. 17 illustrates a plot of relative radiation intensity delivered to a photosensitive layer 70 according to one embodiment of the present invention. Additional reference is made to FIG. 6 that illustrates layer 70 subjected to a flood of incident light 80. FIG. 17 depicts a relative intensity of radiation delivered laterally across photosensitive layer 70. In particular, the relative intensity of radiation delivered to photosensitive layer 70 in regions above dielectric field 58 is below a threshold energy level T_{E}. The relative intensity of radiation delivered to photosensitive layer 70 in regions immediately above plugs 54 is above the threshold energy level T_{E}, due to a combination of incident radiation and reflected radiation reflected by plugs 54 at surface 62.

The threshold energy level T_{E} is selectively controlled as a function of incident radiation intensity, exposure time, exposure area, and thickness of the photosensitive layer 70. As a point of reference, delivering an exact threshold energy density T_{E} via one incident stream to a photosensitive layer to achieve sufficient exposure is difficult, if not impossible, to control. However, delivering substantially less than the threshold energy level T_{E} is easier to control. Thus, aspects of the present invention provide an efficient and precise methodology of flood exposing photosensitive layer 70 with a relative intensity of light of less than T_{E} and employing a reflected portion of light energy from plugs 54 to “impulse” above T_{E} in portions immediately above plugs 54.

In particular, the incident radiation intensity (and hence the reflected radiation intensity) is selected such that each component by itself is inadequate to activate (i.e., expose) the photosensitive layer 70. However, in areas where both the incident and reflected intensity are present, the threshold energy density T_{E} is exceeded and the photosensitive layer 70 in that area is exposed/activated. The mechanism of this is similar to multiple exposure interferometric lithography, and is employed as described above, to mask-lessly align sub-lithographic features onto semiconductor substrates.

FIG. 17 illustrates a step-like function in relative intensity. In this regard, the slope between regions of less than T_{E} and regions of greater than T_{E} is very high (mathematically infinite). In this regard, the higher the slope (i.e., contrast) between unexposed regions (less than T_{E}) and exposed regions (greater than T_{E}), the more “cleanly” recesses 94 (FIG. 8) can be formed. That is to say, the aerial image modulation is smaller.

FIG. 18 illustrates a selective control of exposure dose and kinetics employed to provide portions 150 of photosensitive layer 70 having sub-lithographic critical dimensions according to one embodiment of the present invention. With additional reference to FIG. 6, a dose of incident radiation is controlled such that a lower portion 150 of photosensitive layer 70 receives a greater intensity of radiation (i.e., a “thresholding” of incident radiation) as compared to remaining portions of photosensitive layer 70.

In this manner, by a selective control of a thickness of layer 70 and reflectivity of plugs 54, lower portions 150 of photosensitive layer 70 can be formed having narrower sub-lithographic dimensions than dimensions of plugs 54. In one embodiment, lower portions 150 of photosensitive layer 70 can be formed having sub-lithographic dimensions of less than approximately 20 nm. In this regard, layer 70 can be either a positive photoresist or a negative photoresist.

In one embodiment, layer 70 is a positive photoresist and portions 150 are exposed to a radiation above the threshold energy level T_{E} and defined in a subsequent wash process that removes the soluble portion of exposed photosensitive layer 70. Light reflected from plugs 54 is focused to a narrow region of high threshold intensity that photosensitizes layer 70 in a sub-lithographically small region central to plugs 54. In this manner, portions 150 are formed having sub-lithographic dimensions that are smaller than the dimension of plugs 54. In at least one embodiment, plugs 54 define a sub-lithographic dimension such that portions 150 define a critical dimension even smaller than the sub-lithographic dimension of plugs 54. In an alternate embodiment, light reflected from plugs 54 is diffused to a wide region of high threshold intensity that photosensitizes layer 70 in a super-lithographically large central region above to plugs 54.

In an alternate embodiment, layer 70 is a negative photoresist and portions 150 are exposed to a radiation above the threshold energy level T_{E} and defined in a subsequent wash process that removes a soluble portion of exposed photosensitive layer 70 from around portions 150. In any regard, a lower portion 150 of photosensitive layer 70 receives a greater intensity of radiation as compared to remaining portions of photosensitive layer 70, thus enabling formation of features having sub-lithographic critical dimensions.

Aspects of the present invention have been described that obviate the use of costly masks in wafer processing. In addition, the tedious and complicated alignment marks/routines employed in masking the substrate relative to the photosensitive layer are no longer needed. Additionally, aspects of the present invention do away with the variety of costly and time-consuming anti-reflective coatings used in the prior art photolithography. Moreover, the features formed by embodiments described herein can include sub-lithographic dimensions, which are of particular utility in reducing reset currents in phase change memory cells.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming features in a semiconductor comprising:
providing a wafer substrate including a surface having a reflective region;
coating the surface with a photosensitive layer;
exposing the photosensitive layer; and
controlling exposure intensity such that the photosensitive layer has an exposed area only in an area adjacent the reflective region.

2. The method of claim 1, comprising:
developing away the photosensitive layer leaving a self-aligned recess at the exposed area.

3. The method of claim 2, comprising:
depositing a material layer over the semiconductor including in the self-aligned recess.

4. The method of claim 1, comprising:
defining a threshold exposure level; and
controlling the exposure intensity to exceed the threshold exposure level in the area adjacent the reflective region.

5. The method of claim 1, comprising:
defining the reflective region to include a reflective plug.

6. The method of claim 1, comprising:
depositing at least one transparent layer onto the surface having a reflective region.

7. A mask-less method of aligning semiconductor wafer layers comprising:
providing a substrate defining a surface comprising at least one light reflective region;
coating the surface with a photosensitive layer;
exposing the coated surface with incident light of a selected dose such that the incident light and light reflected from the light reflective region combine to expose the photosensitive layer immediately above the light reflective region;
removing one of an unexposed photosensitive portion and exposed photosensitive portion of the photosensitive layer immediately above the light reflective region; and
depositing a subsequent layer that self-aligns relative to the light reflective region.

8. The method of claim 7, wherein depositing a subsequent layer includes depositing one of a sub-lithographic and a super-lithographic layer self-aligned relative to the light reflective region.

9. The method of claim 7, wherein providing a substrate includes providing a substrate defining a surface comprising a plurality of light reflecting metal plugs dispersed in a substantially light absorbing dielectric region.

10. The method of claim 7, wherein the photosensitive layer is one of a positive photoresist and a negative photoresist layer.

11. The method of claim 7, wherein printing includes one of flood printing and blanket printing.

12. The method of claim 7, wherein providing a substrate includes providing a substrate including at least one metal light reflective plugs disposed in a dielectric field, and depositing a subsequent layer includes depositing a phase-change material onto the at least one metal light reflective plug.

13. A method of forming a feature on a semiconductor wafer comprising:
providing a substrate defining a surface comprising at least one light reflective region adjacent to a substantially non-reflective region;
coating the surface with a photoresist layer;
printing the photoresist coated surface with incident light of a selected dose such that the incident light and light reflected from the light reflective region combine to expose the photoresist layer immediately above the light reflective region; and
removing one of the photoresist layer and the exposed photoresist layer to form the feature.

14. The method of claim 13, wherein the surface comprises at least one metal plug disposed in a dielectric field, each metal plug defining the at least one light reflective region and the dielectric field defining the substantially non-reflective region.

15. The method of claim 13, wherein the surface is coated with a positive photoresist that is substantially insoluble in a developer solution, and further wherein printing the photoresist coated surface includes printing the positive photoresist coated surface with incident light of a selected dose such that the incident light and light reflected from the light reflective region combine to expose and make soluble the positive photoresist immediately above the light reflective region.

16. The method of claim 15, wherein removing includes removing the exposed soluble positive photoresist immediately above the light reflective region by rinsing with the developer solution.

17. The method of claim 13, wherein the surface is coated with a negative photoresist that is completely soluble in a developer solution, and further wherein printing the photoresist coated surface includes printing the negative photoresist coated surface with incident light of a selected dose such that the incident light and light reflected from the light reflective region combine to expose and make insoluble the negative photoresist immediately above the light reflective region.

18. The method of claim 17, wherein removing includes removing the soluble negative photoresist from the surface by rinsing with the developer solution and leaving the exposed insoluble negative photoresist immediately above the light reflective region.

19. A method of forming a phase change memory cell comprising:
providing a semiconductor substrate comprising a resistive element disposed in a dielectric field, the resistive element defining a light reflective region and the dielectric field defining a substantially non-reflective region;
coating the substrate with a positive photoresist;
printing the positive photoresist with incident light of a selected dose such that the incident light and light reflected from the light reflective region combine to expose and make soluble the positive photoresist immediately above the resistive element;
removing the exposed soluble positive photoresist immediately above the resistive element; and
depositing a programmable element onto the resistive element.

20. The method of claim 19, wherein the programmable element defines a planar area in contact with an area of the resistive element, and further wherein the planar area of the programmable element is not greater than the area of the resistive element.

21. The method of claim 19, wherein providing a semiconductor substrate includes providing a semiconductor substrate comprising a metal plug disposed in a dielectric field.

22. The method of claim 19, wherein printing the positive photoresist with incident light includes projection printing a flood of high intensity UV light onto the positive photoresist.

23. The method of claim 19, further comprising depositing at least one layer subsequent to depositing the programmable element onto the resistive element.

24. A method of forming a memory cell comprising:
providing a semiconductor substrate defining a resistive element in a dielectric field, the resistive element defining a contact area; and
exposure means for depositing a programmable element onto the resistive element such that an area of the programmable element is not greater than the contact area of the resistive element.

25. The method of claim 24, wherein providing a semiconductor substrate includes providing a semiconductor substrate including a plurality of metal plugs disposed in a dielectric field.

26. The method of claim 24, wherein exposure means for depositing a programmable element includes coating the substrate with a photoresist and mask-lessly printing the photoresist with high intensity UV light.

27. The method of claim 24, wherein exposure means for depositing a programmable element includes aligning the programmable element onto the resistive element without employing an overlay.

28. The method of claim 24, wherein exposure means for depositing a programmable element includes depositing a phase-change material onto the resistive element.

29. The method of claim 24, wherein the area of the programmable element defines at least one sub-lithographic dimension of less than approximately 50 nanometers.

30. A semiconductor wafer comprising:
an array of memory cells, each memory cell including a plug and a feature aligned relative to the plug;
wherein the feature is defined by a mask-less process comprising flood printing a photosensitive layer with incident light of a selected dose such that the incident light and light reflected from the plug combine to expose only the photosensitive layer immediately above the plug.

31. The semiconductor wafer of claim 30, wherein the feature defines a sub-lithographic critical dimension of less than approximately 50 nm.

32. The semiconductor wafer of claim 30, wherein the plug is a resistive element and the feature comprises a phase change memory material in contact with the plug.
